(19) United States
(12) Patent Application Publication
(10) Pub. No.: US 2004/0099945 A1
(43) Pub. Date: May 27, 2004

(54) IC package for a multi-chip module

(75) Inventor: Shih-Chang Ku, Taipei (TW)

Correspondence Address: BRUCE H. TROXELL, 5205 LEESBURG PIKE, SUITE 1404, FALLS CHURCH, VA, 22041, US

(73) Assignee: Via Technologies, Inc.

(21) Appl. No.: 10/445,435

(22) Filed: May 28, 2003

(30) Foreign Application Priority Data
Nov. 27, 2002 (TW) 91219159

(51) Int. Cl. H01L 23/34; H05K 7/20

(52) U.S. Cl. 257/713; 361/719

(57) ABSTRACT

An IC package for a multi-chip module includes a substrate, a plurality of chips mounted on the substrate, and an encapsultant sealing the chips on the substrate. The IC package is characterized in that at least a thermal bridge is constructed with the encapsultant and each of the thermal bridge is used to bridge at least two chips. By providing the thermal bridge, heat transfer between chips can be upgraded and thereby overall heat-spreading effect and heat dissipation of the multi-chip module can be enhanced.

### BACKGROUND OF THE INVENTION

(1) Field of the Invention

The invention relates to an IC package for a multi-chip module, and more particularly to a package structure which provides an inserted thermal piece to bridge at least two chips and so as to enhance thermal spreading effect inside the package.

(2) Description of the Prior Art

In the application of electronic devices with multi-chip modules (MCM), the ball grid array (BGA) package is one of popular package types. As shown in FIG. 1, a typical BGA package top view for an MCM comprises a substrate 10, a plurality of chips (say, a first chip 30 and a second chip 31 as shown) separately mounted on the substrate 10, and an encapsultant 20 securing the chips 30,31 on the substrate 10. It is noted in FIG. 1 that a BGA structure located under the substrate 10 is not illustrated. In the art, the encapsultant 20 is usually made of epoxy molding compound.

Referring to FIG. 2, a cross-sectional view along line a-a of FIG. 1 is shown. It is clear to see that the second chip 31 covered by the encapsultant 20 is located on of the substrate 10 and thermal balls 11 of the BGA structure as an interface for bridging electrically the second chip 31 and an external device are constructed under the substrate 10.

In the art, any MCM electronic device having a structure resembling that shown in FIG. 1 and FIG. 2 usually has a problem in heat-dissipation. As the structure shown in FIG. 1 and FIG. 2, it can be seen that two of major heat sources are the first chip 30 and the second chip 31. Pathways for dissipating the heat generated in the structure to the surrounding can be: 1) one through the encapsultant 20, and 2) another through the substrate 10 and the thermal balls 11. Generally speaking, the encapsultant 20 has a pretty low thermal conductivity so that most of the heat generated inside the electronic device (about 90%) takes the pathway out through the substrate 10 and the thermal balls 11. It is empirical to know that the heat-dissipation pathways of the first chip 30 and the second chip 31 are basically independent though the first chip 30 and the second chip 31 are covered by the same encapsultant 20.

In aforesaid package structure, the encapsultant 20 does not play a crucial role in heat dissipation of the electronic device obviously though it does occupy major volume of the device. One of reasons why the encapsultant 20 performs poorly in heat dissipation is that the material, usually the epoxy molding compound, has a low heat conductivity and so that it can't transfer rapidly the heat generated by the chips 30,31. That is to say that the encapsultant 20 performs poor heat-spreading in the package structure shown in FIG. 1 and FIG. 2. Apparently, major heat-dissipating of the structure thereof is through the pathway established by the substrate 10 and the thermal balls 11. Nevertheless, it is noted that the space for free air flow under the substrate 10 after the electronic device is mounted onto a print circuit board is limited. Also, it is well known that the print circuit board always performs poorly in heat conduction. Upon such an arrangement of the electronic device mounted closely on the print circuit board in the art, a retardation for heat dissipating via the substrate 10 and the thermal balls 11 can be formed. Definitely, the retardation will affect badly and directly the performance of the chips 30 and 31.

As a resort to improve the aforesaid phenomenon, a drop-in heat spreader BGA (HSBGA) as typically shown in FIG. 3 is introduced to enhance the heat-dissipation efficiency of the BGA structure. Compared with the structure of FIG. 2, the HSBGA adds a heat spreader 40 into the encapsultant 20. Empirically, the heat spreader 40 to boost the heat-spreading sideward can increase the share of heat dissipation of the encapsultant 20 to the whole structure to 25-30%. That is to say that the heat-dissipating through the substrate 10 and the thermal balls 11 as well as the print circuit board can be reduced to 70-75%.

It is well known in the art that the manufacturing tolerance for arranging the heat spreader 40 into the HSBGA structure is particularly strict so as to prevent the package from any defect like bleeding, flash, short, wire sweep or the like. Moreover, because the top surface 41 of the heat spreader 40 is exposed to the atmosphere while in use, it is quite possible that some moisture may be introduced into the electronic device so that unexpected performance bias or distortion may occur. In addition, it is noted that the heat spreader 40 doesn't contact directly with the chips 30 and 31. Therefore, the heat transfer from the chip 30 or 31 to the heat spreader 40 still needs the encapsultant 20 in between as an intermediary. It is also noticeable that the independence in heat dissipation of the chips 30 and 31 is still substantially not changed to the structure shown in FIG. 3, though empirically the whole efficiency in heat dissipation of the electronic device may be enhanced by introducing the heat spreader 40.

As mentioned above, each chip in an MCM electronic device usually has its own heat dissipation pattern or pathway. For an MCM electronic device, a catastrophic situation is one that all chips in the device have individual operation peaks meet at the same time. Thus, in a conventional design, various heat generation timings (or say, operation timings) for chips inside an MCM electronic device are preferably arranged to be offset from each other so that the heat staying inside the device, generated by the chips, won't be accumulated too much to a degree that affects the operation of the electronic device. As the electronic device shown in FIG. 1 and FIG. 2 for an example, a preferable arrangement upon various operation timings is to have the first chip 30 operate while the second chip 31 is off and vice versa.

Therefore, in view of the heat transfer design of the MCM electronic devices, it is usual the case that the most heat-generation chip is the only one to be considered. Surely, such an design treatment shall always live with the independence in heat dissipation of the chips and the predetermined offset control upon the operation timings of the chips in the MCM electronic device. It is obvious that the package formation under the aforesaid design for the multi-chip module is safe but only seems to be overdone for other chips in the same module.

Among various materials used in the electronic device, the silicon that forming the chips is the one who has better heat-spreading and heat-dissipating effect. The heat conductivity of the silicon is higher by ten times or even hundred times than any other material seen in the same package such as the epoxy for the encapsultant or the complex material for the print circuit board. Though the silicon-made chip can perform a better heat transfer medium theoretically, yet the chip in a traditional design still plays a role of heat source in the MCM electronic device, not a role of heat spreading medium which can be used by other chips in the same module. The reason for the situation is quite clear from viewing the structure shown in FIG. 1. As shown, a substantial amount of encapsultant 20 material and a predetermined spacing are always there between the first chip 30 and the second chip 31, and thus the heat generated by one specific chip 30 or 31 are mostly dissipated through the substrate 10 and the thermal balls 11, not detour through the encapsultant 20, another chip 31 or 30, the substrate 10 and the thermal balls 11 finally.

Accordingly, the present invention aims at improving the heat dissipation efficient of the MCM electronic device by involving at least two chips in dissipating the heat generated by a single chip so that a second heat-dissipation pathway through another silicon already existing in the same module can then be established.

### SUMMARY OF THE INVENTION

Accordingly, it is a primary object of the present invention to provide an IC package for a multi-chip module which utilizes a thermal bridge to establish a rapid heat-dissipation pathway between chips and so that the electronic device having the multi-chip module can have better heat-spreading performance and more efficient heat dissipation.

The IC package for a multi-chip module in accordance with the present invention comprising a substrate, a plurality of chips separately mounted on the substrate and an encapsultant covering and sealing the chips on the substrate is characterized in that at least a thermal bridge is included in the encapsultant and each the thermal bridge connects at least two of the chips. By constructing a rapid heat-transfer pathway provided by the thermal bridge, various chips can then be integrated as a whole to share the dissipation of heat generated by any particular chip.

In one embodiment of the present invention, the thermal bridge of the IC package can include at least an aperture.

In one embodiment of the present invention, the encapsultant of the IC package can have an upper side and at least one of the thermal bridge has an upper bridge side. With respect to the substrate, the upper side locates farther than the upper bridge side. That is, part of the encapsultant material exist between the upper side and the upper bridge side.

In one embodiment of the present invention, when part of the encapsultant exist between the upper side and the upper bridge side, this part of the encapsultant can include at least an upper well that connects the upper side of the encapsultant with the upper bridge side of the thermal bridge.

In one embodiment of the present invention, the encapsultant can have an upper side and at least one of the thermal bridges can have an upper bridge side which is exposed exteriorly to the upper side and the atmosphere.

In one embodiment of the present invention, the thermal bridge can have an interior air cavity. Preferably, the thermal bridge is formed as a thermal heat pipe structure.

In one embodiment of the present invention, the encapsultant can have a lateral side and at least one of the thermal bridges can have a lateral bridge side which spaces from the lateral side by part of the encapsultant. That is, the lateral bridge side is buried in the encapsultant.

In one embodiment of the present invention, the encapsultant can have a lateral side and at least one of the thermal bridges can have a lateral bridge side which is exposed exteriorly to the lateral side and the atmosphere.

In one embodiment of the present invention, the thermal bridge of the IC package for the multi-chip module can include at least a thermal abutment for connecting the thermal bridge respectively with one of the chips.

In the present invention, the thermal bridge can be shaped as a block structure, a plate structure, an arch structure, or any other configuration the like.

All these objects are achieved by the IC package for a multi-chip module described below.

### BRIEF DESCRIPTION OF THE DRAWINGS

The present invention will now be specified with reference to its preferred embodiment illustrated in the drawings, in which

FIG. 1 is a perspective view of a conventional package of a multi-chip module;

FIG. 2 is a cross-sectional view of FIG. 1 along line a-a;

FIG. 3 is a cross-sectional view of another conventional package of a multi-chip module;

FIG. 4 is an exploded perspective view of an embodiment of the IC package for a multi-chip module in accordance with the present invention;

FIG. 5A is a cross-sectional view showing a top-side relationship embodiment between the encapsulant and the thermal bridge of the IC package for a multi-chip module according to the present invention;

FIG. 5B is a cross-sectional view showing another top-side relationship embodiment between the encapsulant and the thermal bridge of the IC package for a multi-chip module according to the present invention;

FIG. 5C is a cross-sectional view showing a further top-side relationship embodiment between the encapsulant and the thermal bridge of the IC package for a multi-chip module according to the present invention;

FIG. 5D is a cross-sectional view showing one more top-side relationship embodiment between the encapsulant and the thermal bridge of the IC package for a multi-chip module according to the present invention;

FIG. 6A is a cross-sectional view showing a lateral-side relationship embodiment between the encapsulant and the thermal bridge of the IC package for a multi-chip module according to the present invention;

FIG. 6B is a cross-sectional view showing another lateral-side relationship embodiment between the encapsulant and the thermal bridge of the IC package for a multi-chip module according to the present invention;

FIG. 6C is a cross-sectional view showing a further lateral-side relationship embodiment between the encapsulant and the thermal bridge of the IC package for a multi-chip module according to the present invention;

FIG. 6D is a cross-sectional view showing one more lateral-side relationship embodiment between the encapsulant and the thermal bridge of the IC package for a multi-chip module according to the present invention;

FIG. 7A is a perspective view of an embodiment of the thermal bridge in accordance with the present invention;

FIG. 7B is a perspective view of another embodiment of the thermal bridge in accordance with the present invention;

FIG. 7C is a perspective view of a further embodiment of the thermal bridge in accordance with the present invention;

FIG. 7D is a perspective view of one more embodiment of the thermal bridge in accordance with the present invention;

FIG. 8 is a perspective bottom view of still one more embodiment of the thermal bridge having a plurality of thermal abutments located thereof in accordance with the present invention;

FIG. 9 is a planar view of another embodiment of the IC package for a multi-chip module in accordance with the present invention, in which the encapsultant has been removed to clearly reveal the relationship of the chips and the thermal bridges; and

FIG. 10 a cross-sectional view of a further embodiment of the IC package for a multi-chip module in accordance with the present invention.

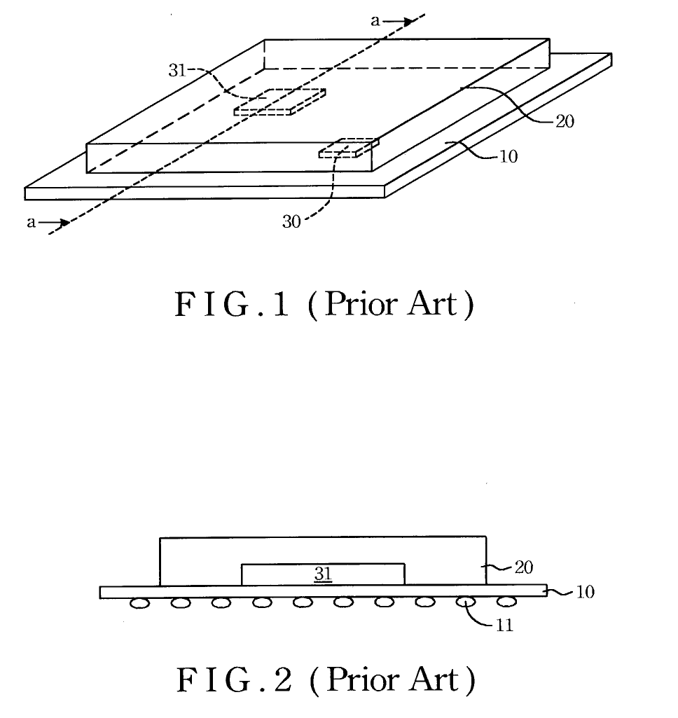

### DESCRIPTION OF THE PREFERRED EMBODIMENT

The invention disclosed herein is directed to an IC package for a multi-chip module. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

In the following description, elements that have same function but slight different shapes will be labeled by the same number and identical name so as to ensure overall consistency.

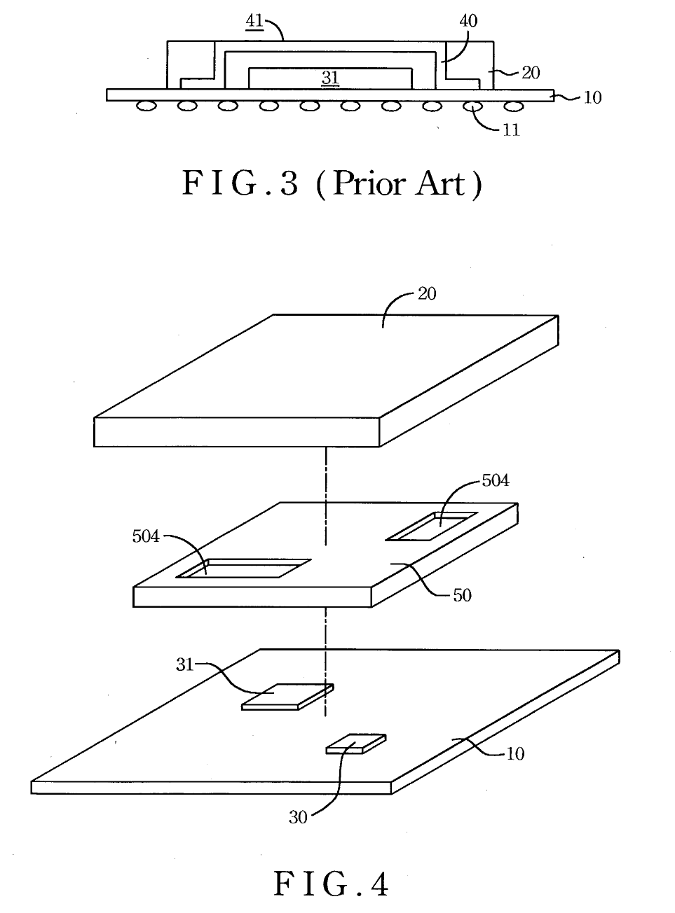

Referring now to FIG. 4, an exploded perspective view of a preferred IC package for a multi-chip module in accordance with the present invention is shown to include a substrate 10, a plurality of chips (say, a first chip 30 and a second chip 31) separately mounted on the substrate 10, an encapsultant 20 for covering and sealing the chips 30,31 on the substrate 10, and at least a thermal bridge 50 (one shown in this embodiment). The thermal bridge 50 for thermally connecting at least two of the chips in the multi-chip module (say, two chips 30,31 in this embodiment) is buried in the encapsultant 20. Upon such an arrangement, a rapid heat-transfer pathway provided by the thermal bridge 50 can thus be established to have various chips integrated as a whole to share the dissipation of heat generated by any particular chip (say, chip 30 or 31).

In the present invention, for providing substantially efficient conductivity, the thermal bridge 50 can transfer the heat directly and rapidly between the chips 30,31. Apparently, with the involvement of the thermal bridge 50, the heat transfer pathways between the chips 30,31 can have a new choice other than the one through the encapsultant 20 and the substrate 10. Thereby, the heat generated by operating any of the chips 30,31 can be rapidly shared by both chips 30,31 and then dissipated therefrom to the surroundings of the electronic device through the respective thermal balls (not shown in the figure) and the print circuit board (not shown in the figure). Obviously, the thermal bridge 50 of the present invention plays a role to deliver the heat at least bi-directionally between the chips 30,31 such that the aforesaid heat dissipation problem in package design and application can be released substantially.

As shown in FIG. 4, the thermal bridge 50 of the IC package can include at least an aperture 504 to accommodate the chips for saving material and facilitating the flow path design in forming the encapsultant 20 on the substrate 10.

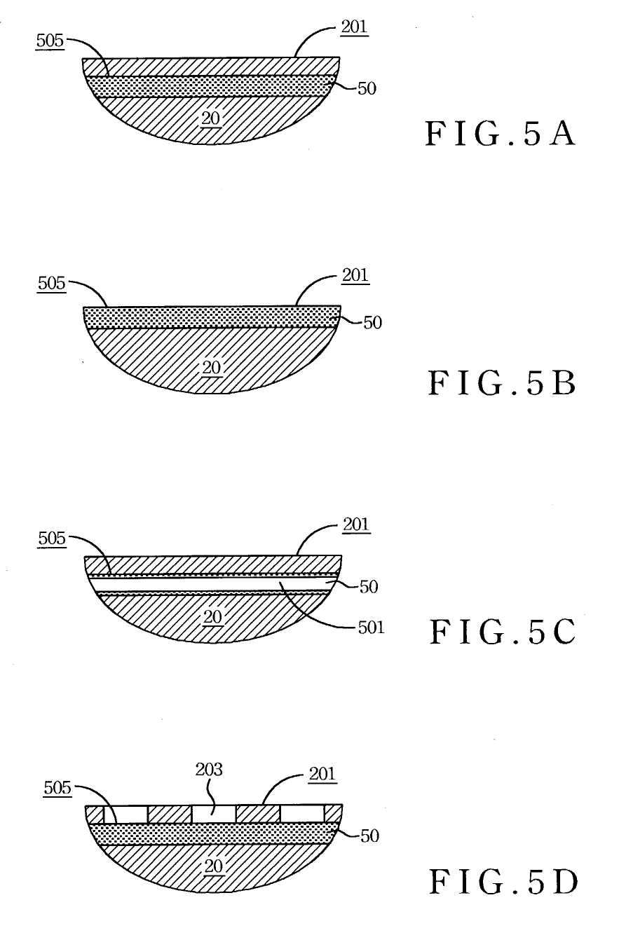

In the present invention, the encapsultant 20 of the IC package can have an upper side and at least one of the thermal bridge 50 can have an upper bridge side. In application, location relationship between the upper side of the encapsultant 20 and the upper bridge side of the thermal bridge 50 can be various. Following, FIG. 5A through FIG. 5D, are some of those examples. As shown in FIG. 5A, with respect to the substrate 10, the upper side 201 of the encapsultant 20 locates higher, i.e. farther, than the upper bridge side 505 of the thermal bridge 50. That is, partial material of the encapsultant 20 exists between the upper side 201 and the upper bridge side 505. As shown in FIG. 5B, the upper bridge side 505 can also expose exteriorly to the upper side 201, and thereby the heat flowing in the thermal bridge 50 can dissipate directly to the atmosphere. As shown in FIG. 5D, when part of the encapsultant 20 exist between the upper side 201 and the upper bridge side 505, this part of the encapsultant 20 can include at least an upper well 203 which connects the upper side 201 with the upper bridge side 505. Upon inclusion of the well 203, the heat flowing in the thermal bridge 50 can then dissipate directly to the air inside the well 203. Also, the well 203 can be used or prepared for any installation of external heat-dissipating apparatus, such as heat pipes, heat-dissipation fin, fans, or any the like.

Referring now to FIG. 5C, the thermal bridge 50 of the present invention may be formed to have an interior air cavity 501. Preferably, the airtight air cavity 501 can contain a proper amount of liquid (not shown) so as to make the thermal bridge 50 formed as a thermal heat pipe structure which has a well-known excellent heat conductivity. In FIG. 5C, the air cavity 501 is constructed with the upper bridge side 505 lower than the upper side 201 of the encapsultant 20. In other embodiments not shown herein, the thermal bridge 50 having the air cavity 501 can also be adopted to any type of location relationship between the upper side 201 and the upper bridge side 505. For the structure and application of the thermal heat pipes are well known in the art, they will be omitted herein.

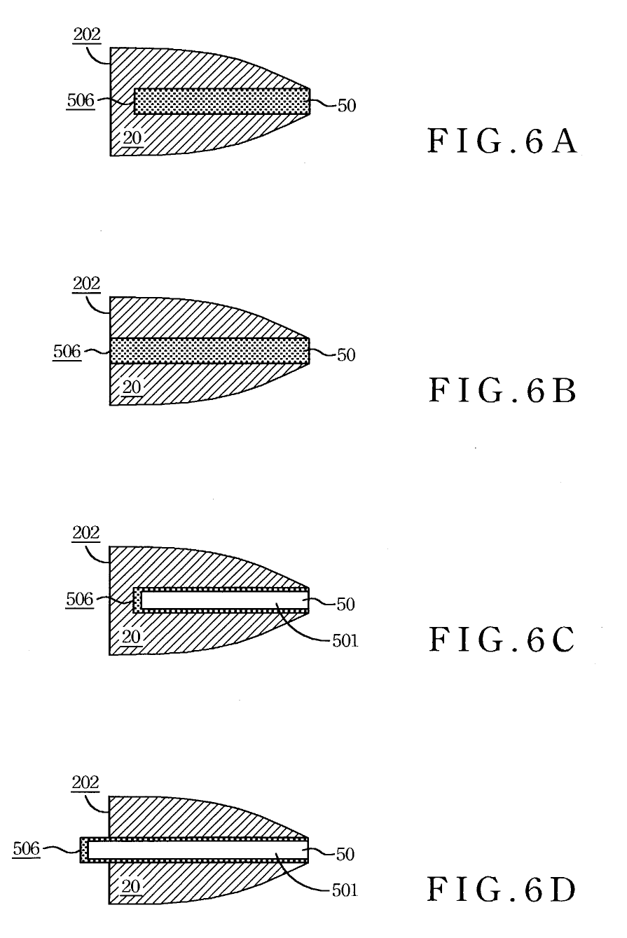

Similarly, in the present invention, the encapsultant 20 can have a lateral side and at least one of the thermal bridges 50 can have a lateral bridge side. In practices, location relationship between the lateral side of the encapsultant 20 and the lateral bridge side of the thermal bridge 50 can be various. Following, FIG. 6A through FIG. 6D, are some of those examples. As shown in FIG. 6, the lateral side 202 of the encapsultant 20 spaces from the lateral bridge side 506 of the thermal bridge 50 by partial material of the encapsultant 20. That is, the lateral bridge side 506 is buried in the encapsultant 20. As shown in FIG. 6B, the lateral bridge side 506 is exposed to, or at least flush with, the lateral side 202 so that the lateral side 506 of the thermal bridge 50 can contact with the surrounding air. As shown in FIG. 6C, an air cavity 501 as the one constructed in previous embodiment of FIG. 5C is included in the thermal bridge 50. As shown in FIG. 6D, the lateral bridge side 506 of the thermal bridge 50 having the air cavity 501 is further extended into the surroundings by compared with the embodiment shown in FIG. 6B.

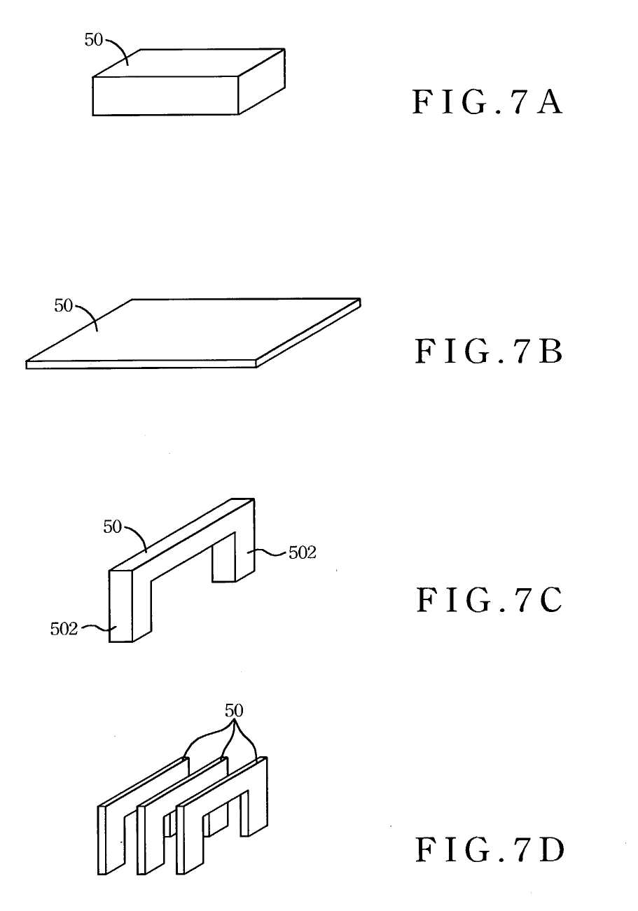

In the present invention, the thermal bridge 50 for the MCM electronic device can be shaped as a block structure as shown in FIG. 7A, a plate structure as shown in FIG. 7B, an arch structure as shown in FIG. 7C, or any other configuration the like.

In FIG. 7C, the arch-shaped thermal bridge 50 may have at least a bridge leg 502 (two shown in the figure) for landing or extending the thermal bridge 50 onto the respective chip. Such a design of bridge legs 502 is especially suitable to the electronic device with a wire bond IC package that has peripheral gold wires.

Other than previous application of the single-piece thermal bridges 50, the thermal bridge 50 of the present invention can also utilized by combinations as the one shown in FIG. 7D, in which three arch-shaped thermal bridges 50 are used in combination style.

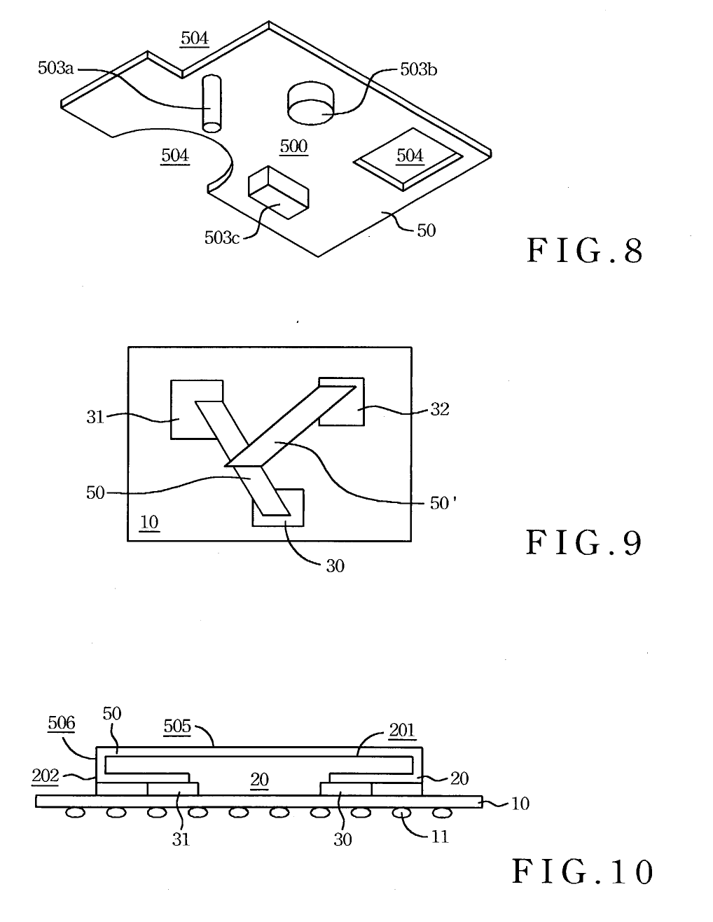

Referring now to FIG. 8, another embodiment of the thermal bridge 50 in accordance with the present invention is exploded shown. In this embodiment, the thermal bridge 50 has a lower bridge side 500 and, on the lower bridge side 500, at least a thermal abutment (three thermal abutments 503a, 503b and 503c in the figure). Each of the thermal abutments 503a, 503b and 503c is used to connect geometrically and thermally the thermal bridge 50 with one respective chip. Also shown in FIG. 8, the thermal bridge 50 is profiled to be a plate structure having three apertures 504. In addition, these three thermal abutments 503a, 503b and 503c differ from each other in configuration and length. Definitely, in practices, the consideration upon the configuration, the length and the inclusion, or not, of the thermal abutments is dependent on the geometrical relation between the thermal bridge 50 and the respective chip.

As shown in FIG. 8, the thermal bridge 50 as a simple piece is used to connect at least three chips by three abutments 503a, 503b and 503c respectively. In another embodiment of the present invention, the connections among chips can also be made by a combination of several thermal bridges 50. Referring now to FIG. 9, a top planar view of an MCM electronic device with the encapsultant removed off is shown. In the embodiment, three chips (say, the first chip 30, the second chip 31 and the third chip 32) are mounted on the substrate 10 and two thermal bridges (say, the first thermal bridge 50 and the second thermal bridge 50′) are applied to establish thermal connection among chips 30,31,32. As shown, for integrating thermally these three chips 30,31,32, the first thermal bridge 50 is used to bridge the first chip 30 and the second chip 31, and the second thermal bridge 50′ is used to extend the thermal connection to the third chip 32 by means of landing one end to the third chip 32 while another to a middle of the first thermal bridge 50.

In the present invention, various combinations of the thermal bridges and the chips can be simply constructed. As the embodiment shown in FIG. 8, a single thermal bridge 50 is used to thermally connect three chips. On the other hand, in FIG. 9, three chips 30,31,32 are integrated thermally by two thermal bridges 50,50′. Therefore, after learning the above disclosure, it can be easily schemed by a skilled person in the art to carry out other combinations of the thermal bridges and the chips in a multi-chip module.

Referring now to FIG. 10, a further embodiment of the IC package for a multi-chip module in accordance with the present invention is cross-sectional shown. In this embodiment, the first chip 30 and the second chip 31 are connected thermally with an arch-shaped thermal bridge 50. In particular, both the lateral bridge side 506 of the thermal bridge 50 are exposed over the lateral side 202 of the encapsultant 20, and the upper bridge side 505 thereof also locates higher that the upper side 201 of the encapsultant 20.

In the present invention, the thermal bridge 50 can be made of gold, copper, aluminum, silicon, or any material which has a preferred heat conductivity. Also, the connection between the thermal bridge and the respective chip can be a gravity one (simple connected by the weight itself), a gluing one, or any adhering connection that can confirm the thermal connection therebetween.

By providing the IC package for a multi-chip module disclosed above, multiple chips in the same module can be successfully thermally connected by the thermal bridges, and thereby better heat-spreading performance and more efficient heat dissipation of the electronic device can thus be guaranteed.

While the present invention has been particularly shown and described with reference to a preferred embodiment, it will be understood by those skilled in the art that various changes in form and detail may be without departing from the spirit and scope of the present invention.

I claim:

1. An IC package for a multi-chip module, comprising:
a substrate;
a plurality of chips separately mounted on the substrate;
at least a thermal bridge connecting at least two of the chips; and
an encapsultant covering the chips.

2. The IC package for a multi-chip module according to claim 1, wherein said thermal bridge comprises thereof at least an aperture.

3. The IC package for a multi-chip module according to claim 1, wherein said encapsultant has an upper side and at least one said thermal bridge has an upper bridge side which spaces from the upper side by part of said encapsultant.

4. The IC package for a multi-chip module according to claim 3, wherein said encapsultant comprises at least an upper well connecting said upper side with said upper bridge side.

5. The IC package for a multi-chip module according to claim 1, wherein said encapsultant has an upper side and at least one said thermal bridge has an upper bridge side which is exposed exteriorly to the upper side.

6. The IC package for a multi-chip module according to claim 1, wherein said thermal bridge has an interior air cavity.

7. The IC package for a multi-chip module according to claim 6, wherein said thermal bridge having said air cavity is formed as a thermal heat pipe structure.

8. The IC package for a multi-chip module according to claim 1, wherein said encapsultant has a lateral side and at least one said thermal bridge has a lateral bridge side which spaces from the lateral side by part of said encapsultant.

9. The IC package for a multi-chip module according to claim 1, wherein said encapsultant has a lateral side and at least one said thermal bridge has a lateral bridge side which is exposed exteriorly to the lateral side.

10. The IC package for a multi-chip module according to claim 1, wherein said thermal bridge is shaped as a block structure.

11. The IC package for a multi-chip module according to claim 1, wherein said thermal bridge is shaped as a plate structure.

12. The IC package for a multi-chip module according to claim 1, wherein said thermal bridge is shaped as an arch structure.

13. The IC package for a multi-chip module according to claim 1 further comprises at least a thermal abutment for connecting said thermal bridge respectively with one said chip.
